(19) United States
(12) Patent Application Publication
(10) Pub. No.: US 2012/0051558 A1
(43) Pub. Date: Mar. 1, 2012

(54) METHOD AND APPARATUS FOR REPRODUCING AUDIO SIGNAL BY ADAPTIVELY CONTROLLING FILTER COEFFICIENT

(75) Inventors: Hae-jong KIM, Seoul (KR); Hae-kwang PARK, Suwon-si (KR); Kyu-eun PARK, Suwon-si (KR)

(73) Assignee: SAMSUNG ELECTRONICS CO., LTD., Suwon-si (KR)

(21) Appl. No.: 13/223,781

(22) Filed: Sep. 1, 2011

Related U.S. Application Data
(60) Provisional application No. 61/379,035, filed on Sep. 1, 2010.

(30) Foreign Application Priority Data
Jul. 7, 2011 (KR) 10-2011-0067533
Aug. 22, 2011 (KR) 10-2011-0083575

(51) Int. Cl. H03G 5/00

(52) U.S. Cl. 381/98

(57) ABSTRACT

A method and an apparatus for reproducing a sound signal are provided. The method includes generating an output sound signal to be transmitted to speakers by transmitting a first input sound signal through a filter; acquiring magnitude information of the output sound signal; determining frequency response parameters related to frequency responses of the filter based on the magnitude information; and adaptively adjusting coefficients of the filter based on the determined frequency response parameters.

### CROSS-REFERENCE TO RELATED APPLICATION

This application claims the benefit of U.S. Provisional Patent Application No. 61/379,035, filed on Sep. 1, 2010, in the U.S. Patent and Trademark Office, and priority from Korean Patent Application No. 10-2011-0067533, filed on Jul. 7, 2011 and Korean Patent Application No. 10-2011-0083575, filed on Aug. 22, 2011, in the Korean Intellectual Property Office, the disclosures of each of which are incorporated by reference herein in their entirety.

### BACKGROUND

1. Field

Methods and apparatuses consistent with the present disclosure relate to reproducing audio signals, and more particularly, to reproducing audio signals by adaptively controlling filter coefficients.

2. Description of the Related Art

Due to increasing demands for sound quality close to real sound, sound processing technologies are rapidly developing. However, due to limited performance of sound outputting devices, such as speakers, distortion occurs in sound signals. Therefore, even if sound signals are restored with a quality that is close to real sounds, speakers with inferior performance cause distortions in sound signals, and thus sound quality is deteriorated.

### SUMMARY

The present disclosure provides a method and an apparatus for reproducing audio signals by adaptively controlling filter coefficients.

According to an aspect of an exemplary embodiment, there is provided a method of reproducing a sound signal, the method including generating an output sound signal to be transmitted to speakers by transmitting a first input sound signal through a filter; acquiring magnitude information of the output sound signal; determining frequency response parameters related to frequency responses of the filter based on the magnitude information; and adaptively adjusting coefficients of the filter based on the determined frequency response parameters.

Determining of the frequency response parameters may include determining frequency response parameters by using a mapping table which includes information regarding mapping between magnitudes of the output sound signal and frequency response parameters.

Determining of the frequency response parameters may include determining the frequency response parameters based on a magnitude of the output sound signal, such that a gain value of a low-frequency component of a second input sound signal, which is input to the filter after the first input sound signal, increases.

Determining of the frequency response parameters may include determining the frequency response parameters, such that, if the magnitude of the output sound signal exceeds a threshold point, the gain value of the low-frequency component of the second input sound signal does not increase.

Determining of the frequency response parameters may include determining the frequency response parameters, such that the gain value of the low-frequency component of the second input sound signal increases in inverse proportion to the magnitude of the output sound signal.

The frequency response parameters may include at least one of a center frequency, a bandwidth corresponding to the center frequency, and a gain value at the center frequency.

The filter may include a pre-processing filter that simultaneously adjusts frequency characteristics of sound signals according to initial frequency response parameters; and a post-processing filter that adaptively adjusts frequency characteristics of sound signals according to a magnitude of a second output sound signal output by the speakers before the first output sound signal.

The filter may be embodied by using at least one of a finite impulse response (FIR) filter and an infinite impulse response (IIR) filter.

According to another aspect of an exemplary embodiment, there is provided a sound signal reproducing apparatus including a filter that generates an output sound signal to be transmitted to speakers from a first input sound signal; a magnitude acquiring unit that acquires magnitude information of the output sound signal; a parameter determining unit that determines frequency response parameters related to frequency responses of the filter based on the magnitude information; and a coefficient adjusting unit that adaptively adjusts coefficients of the filter based on the determined frequency response parameters.

According to another aspect of an exemplary embodiment, there is provided a sound signal reproducing apparatus comprising a filter that generates an output sound signal to be transmitted to speakers from a first input sound signal, the output sound signal being generated according to one or more filter coefficients; a magnitude acquiring unit that acquires magnitude information of the output sound signal prior to the output sound signal being transmitted to the speakers; a parameter determining unit that determines frequency response parameters of the filter based on the magnitude information; and a coefficient adjusting unit that adaptively adjusts the filter coefficients of the filter based on the determined frequency response parameters.

### BRIEF DESCRIPTION OF THE DRAWINGS

The above and other aspects will become more apparent by describing in detail exemplary embodiments thereof with reference to the attached drawings in which:

FIG. 1 is a block diagram of a sound signal reproducing apparatus according to an exemplary embodiment;

FIG. 2 is a detailed block diagram of a sound signal reproducing apparatus according to an exemplary embodiment;

FIG. 3 is a detailed block diagram of the sound signal reproducing apparatus according to another exemplary embodiment;

FIGS. 4A and 4B show, respectively, an example of frequency response characteristics of a related art sound signal reproducing apparatus and frequency response characteristics of a sound signal reproducing apparatus according to an exemplary embodiment; and

FIG. 5 is a flowchart showing a method of reproducing a sound signal according to an exemplary embodiment.

### DETAILED DESCRIPTION

Hereinafter, exemplary embodiments will be described in detail with reference to the accompanied drawings.

The term “cut off frequency” denotes a frequency at a point of time at which a gain of a transfer function numerically expressing frequency response characteristics decreases by a certain amount in comparison to a reference value (e.g., a maximum value).

The term “bandwidth” denotes a frequency bandwidth between an upper cut-off frequency and a lower cut-off frequency. In other words, the bandwidth is a value acquired by subtracting a lower cut-off frequency from an upper cut-off frequency.

The term “center frequency” denotes a frequency between of an upper cut-off frequency and a lower cut-off frequency. The center frequency may be a frequency corresponding to the pole of a transfer function.

The term “Q factor” indicates a value indicating sharpness of a transfer function. The greater a Q factor is, the sharper a transfer function becomes. The smaller a Q factor is, the smoother a transfer function becomes. A Q factor may be a value acquired by dividing bandwidth by center frequency.

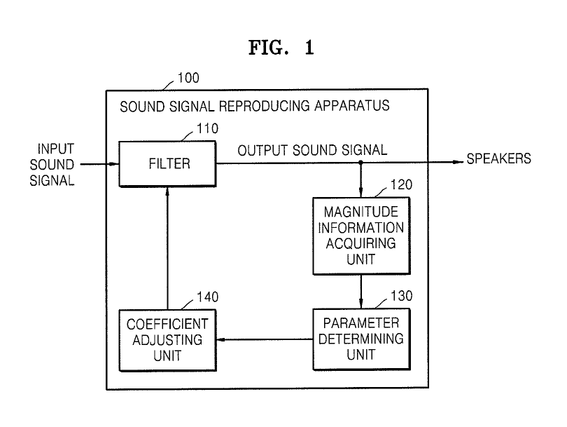

FIG. 1 is a block diagram of a sound signal reproducing apparatus 100 according to an exemplary embodiment. The sound signal reproducing apparatus 100 includes a filter 110, a magnitude information acquiring unit 120, a parameter determining unit 130, and a coefficient adjusting unit 140.

The filter 110 transmits input sound signals therethrough and generates output sound signals to be output via speakers. The filter 110 may be embodied by using an infinite impulse response (IIR) filter, a finite impulse response (FIR) filter, or both an IIR filter and a FIR filter.

The filter 110 may include both a pre-processing unit (not shown in FIG. 1) and a post-processing unit (not shown) or may include either the pre-processing unit or the post-processing unit (not shown).

The pre-processing unit may include one or more modules, such as a parameter equalizer (PEQ), a dynamic range control (DRC), etc., and input sound signals are amplified in stages as the input sound signals pass through each of the modules.

The PEQ processes input sound signals, such that the processed sound signals have uniform frequency characteristics. When input sound signals pass through one or more modules, the input sound signals may be deformed into signals with non-uniform frequency characteristics due to the characteristics of the modules. For example, low frequency components in the input sound signal may decrease. In this case, the PEQ amplifies low frequency components, so that the input sound signals, which passed through the one or more modules, have uniform frequency characteristics. The sound signal reproducing apparatus 100 has preset PEQ parameters and adjusts frequency characteristics by using the PEQ parameters.

The DRC adjusts frequency characteristics of the input sound signals by reflecting characteristics of speakers. It is assumed that output sound signals include frequency components that cannot be output by the speakers. The frequency components that cannot be output by the speakers are either output in distorted forms or emitted in the form of unnecessary energy, e.g., heat. Undesired energy, such as distorted the frequency components or heat, may deteriorate the reliability of the speakers and the sound signal reproducing apparatus 100 itself. Similarly, output sound signals exceeding the maximum output of the speakers may cause sound signal distortions or unnecessary energy generation. The DRC prevents deterioration in the reliability of the speakers and sound systems due to distortions in the sound signals or due to the generation of undesired energy by removing from he sound signals components that cannot be handled by the speakers or that are inappropriate to be processed by the speakers.

The post-processing unit is a type of equalizer for controlling frequency characteristics of input sound signals. The post-processing unit functions similar to a PEQ. However, while the PEQ uniformly adjusts the frequency characteristics of the input sound signals according to initial frequency response parameters, the post-processing unit adaptively adjusts frequency characteristics by changing frequency response parameters and filter coefficients according to a determination of the parameter determining unit 130 and the filter coefficient determining unit 140 described below.

According to exemplary embodiments, the pre-processing unit may also function as the post-processing unit. In other words, when the sound signal reproducing apparatus 100 is initially manufactured, the PEQ adjusts the frequency characteristics of the input sound signals according to initial frequency response parameters. However, after the sound signals are output via the speakers, the PEQ may adaptively change frequency response parameters according to determinations of the parameter determining unit 130 and the filter coefficient determining unit 140, as described below.

The magnitude information acquiring unit 120 acquires magnitude information regarding output sound signals that are output via the speakers.

The parameter determining unit 130 determines frequency response parameters related to a frequency response of the filer 110 based on the magnitude information regarding the output sound signal. The frequency response parameters related to the frequency response of the filter 110 may include at least one of a center frequency, a bandwidth, a cut-off frequency, a gain value at the center frequency, a sharpness of a frequency response function, and a Q factor. However, other parameters that relate to the frequency response and depend at least in part on the magnitude information may also be determined.

If the cut-off frequency is adjusted to reduce the bandwidth, or if the Q factor is increased, the sharpness of a transfer function nearby the center frequency increases. As a result, the gain value at the center frequency increases.

Accordingly, the parameter determining unit 130 may increase a gain value in a desired frequency band. Generally, a sound signal features a relatively small gain value of a low-frequency component compared to a gain value of a high-frequency component, and thus the parameter determining unit 130 may change the Q factor or the cut-off frequency to increase the gain value of the low-frequency component. Here, in a case where the magnitude of an output sound signal exceeds a threshold value, the speakers may not be able to successfully output the sound signal if the gain value of low-frequency component is increased. For example, distortion may occur. Therefore, in a case where the magnitude of an output sound signal exceeds a threshold value, it may be advantageous not to change frequency parameters, or to change the frequency parameters so as to not to exceed the maximum output of the speakers.

For example, even if the magnitudes of an output sound signal that does not exceed the maximum output of the speakers are from 0 to 1, a gain value of low-frequency component is increased only if the magnitude of the output signal is from 0 to 0.7, and a gain value of the low-frequency component is not changed if the magnitude of the output signal exceeds 0.7.

The parameter determining unit 130 may determine the frequency response parameters by using a mapping table which includes information regarding mapping between magnitudes of the output sound signal and the frequency response parameters. The mapping table takes into consideration a sound pressure level characteristic of a digital amplifier or speaker. The sound pressure level characteristic denotes a value indicating a ratio of a magnitude of a change of pressure within a medium during transmission of the sound signal with respect to a reference sound pressure, and is an example of one type of information indicating the characteristics of the speakers.

The mapping table includes pre-calculated Q factors or cut-off frequencies that are the most suitable for various frequency bands (e.g., a low frequency band). Therefore, the parameter determining unit 130 may determine the most suitable frequency parameters without having to calculate frequency parameters every time the magnitude of an output sound signal is changed.

It is not necessary for the mapping table to include information regarding frequency parameters respectively corresponding to all magnitudes of output sound signals. In consideration of the amount of data stored in the mapping table and efficiency, magnitudes of output sound signals may be categorized in a plurality of levels and the mapping table may in such a case include only frequency parameters respectively corresponding to the plurality of levels.

The coefficient adjusting unit 140 adaptively adjusts coefficients of the filter 110 based on frequency response parameters. Adaptive adjustment of coefficients of the filter 110 denotes automatic adjustment of coefficients of the filter 110 according to changes in environment (e.g., a change in a magnitude of the output sound signal).

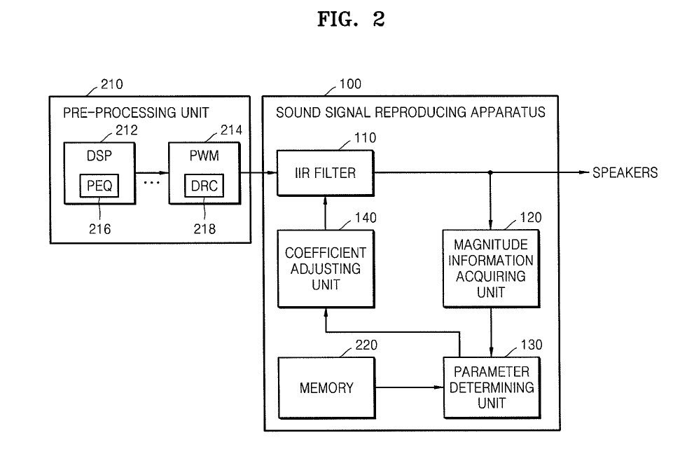

FIG. 2 is a detailed block diagram of a sound signal reproducing apparatus 100 according to an exemplary embodiment.

FIG. 2 shows a case in which an IIR filter 110 is designed as a module independent from a pre-processing unit 210. Hereinafter, operations of blocks of the sound signal reproducing apparatus 100 will be described in chronological order with the assumption that a first input sound signal and a second input sound signal are input to the pre-processing unit 210 in the order stated.

When the first input sound signal is received by the pre-processing unit 210, the pre-processing unit 210 amplifies the first input sound signal and generates a first output sound signal. In detail, the first input sound signal is amplified in stages via a PEQ 216, a DRC 218, a microcomputer (not shown), a digital signal processing (DSP) unit 212, and a pulse width modulation (PWM) unit 214. However, the pre-processing unit 210 is designed to initially have frequency response characteristics when the pre-processing unit 210 is manufactured, and the frequency response characteristics are applied regardless of the characteristics of the input sound signals. Therefore, even if distortion occurs when the first input sound signal which has passed through the pre-processing unit 210 is output via the speakers, the pre-processing unit 210 does not perform any correction.

A first output sound signal output by the pre-processing unit 210 passes through the IIR filter 110. Coefficients of the IIR filter 110 will have been changed based on a magnitude of a previously output sound signal.

The first output sound signal which has passed through the IIR filter 110 is output via the speakers.

The magnitude information acquiring unit 120 acquires magnitude information from the first output sound signal before the first output sounds signal is output via the speakers.

The parameter determining unit 130 receives magnitude information from the magnitude information acquiring unit 120. The parameter determining unit 130 acquires at least one of first mapping information indicating mapping between magnitudes of sound signals and Q factors, and second mapping information indicating mapping between magnitudes of sound signals and cut-off frequencies from a memory 220 and searches for Q factors and cut-off frequencies corresponding to the magnitude information acquired by the magnitude information acquiring unit 120 by using at least one of the first mapping information and the second mapping information.

The coefficient adjusting unit 140 adjusts coefficients of the IIR filter 110 based on the Q factors and the cut-off frequencies determined by the parameter determining unit 130.

Next, the second input sound signal is input to the pre-processing unit 210.

The pre-processing unit 210 generates a second output sound signal by processing the second input sound signal. As described above, the pre-processing unit 210 has the same frequency response characteristics regardless of distortions in previously output sound signals.

The second output sound signal output by the pre-processing unit 210 is transmitted to the speakers via the IIR filter 110. The IIR filter 110 has changed coefficients different from the initial coefficients. The changed coefficients of the IIR filter 110 are changed based on the previously output sound signals (i.e., the first output sound signals). Generally, magnitudes and characteristics of sound signals that are input at time points close to each other are similar to each other. Therefore, the magnitude and characteristics of the first output sound signal and the second output sound signal are likely to be similar to each other. Therefore, frequency response characteristics of the IIR filter 110 at a current time point are likely to be suitable for the second output sound signal.

Each of the modules in a related art reproducing apparatus is unable to acquire information regarding final output signals, and thus coefficients of the modules cannot be changed based on output signals. Therefore, even if distortion occurs in an output signal, the distortion is not automatically corrected, and thus sound quality is deteriorated. However, in the sound signal reproducing apparatus 100 according to exemplary embodiments, final output sound signals are analyzed before the final output sound signals are output via the speakers, and parameters of the internal modules of the sound signal reproducing apparatus 100 are adaptively adjusted if distortion occurs or is likely to occur. Therefore, sound quality may be improved.

Furthermore, since coefficients of the IIR filter 110 are adjusted based on the magnitude of the output sound signal right before the output sound signal is to be output, it is not necessary to measure frequency response characteristics of the sound signal reproducing apparatus 100 by using an external device. In the case of measuring frequency response characteristics by using an external device, frequency response characteristics due to the external device are included in the measured frequency response characteristics, and thus it is difficult to measure frequency response characteristics of the sound signal reproducing apparatus 100 only. Therefore, overall system complexity may increase. However, according to exemplary embodiments, overall system complexity may be significantly reduced in the case of measuring frequency response characteristics of the sound signal reproducing apparatus 100.

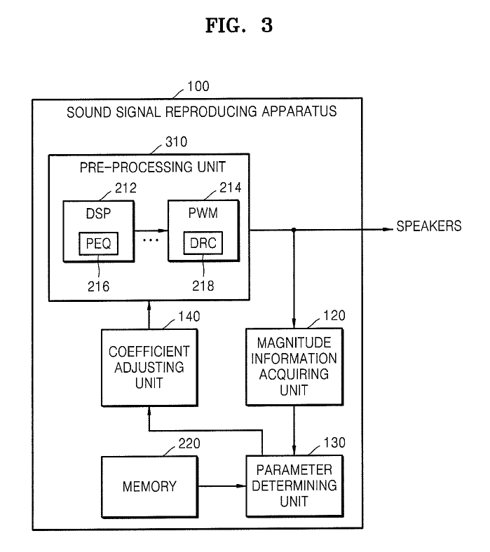

FIG. 3 is a detailed block diagram of the sound signal reproducing apparatus 100 according to another exemplary embodiment.

The sound signal reproducing apparatus 100 shown in FIG. 3 is similar to the sound signal reproducing apparatus 100 shown in FIG. 2, except that the pre-processing unit 310 functions as the IIR filter 110 of FIG. 2. In other words, as shown in FIG. 3, parameters of internal modules of the pre-processing unit 310, such as a PEQ, may be adjusted based on magnitude information of the output sound signal, so that the same effect as that of FIG. 2 may be achieved.

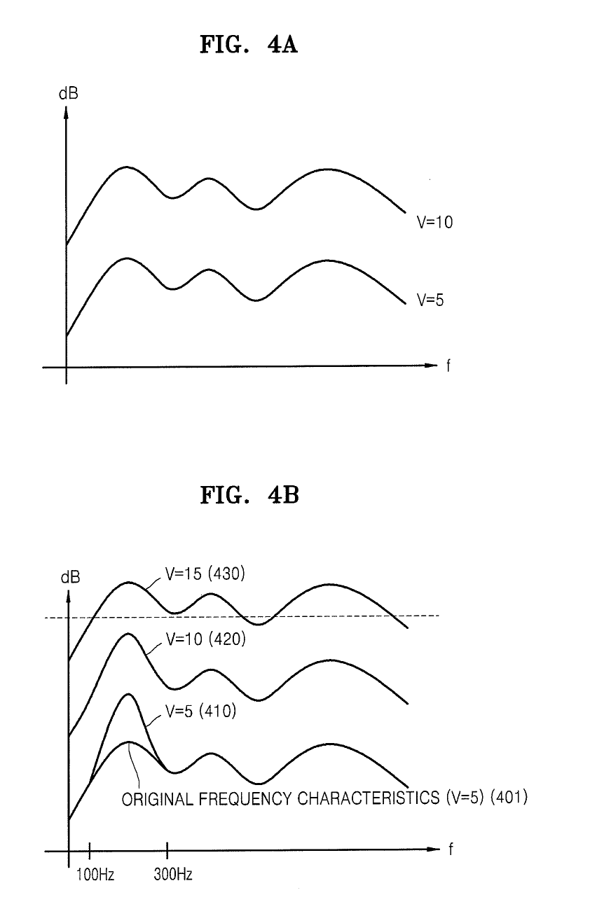

FIG. 4A shows frequency responses of a related art sound signal reproducing apparatus.

Referring to FIG. 4A, the related art sound signal reproducing apparatus has the same frequency responses regardless of the magnitudes of output sound signals. In other words, a gain value increases according to the magnitudes of the input sound signals, but the shapes of the waveforms are the same.

FIG. 4B shows frequency response characteristics of the sound signal reproducing apparatus 100 according to an exemplary embodiment.

Referring to FIG. 4B, frequency response characteristics of the sound signal reproducing apparatus 100 vary according to the magnitudes of the output sound signals.

In a case where it is determined that a magnitude of an output sound signal is sufficiently small such that no distortion is likely to occur in the output sound signal, the sound signal reproducing apparatus 100 changes the frequency response characteristics of the filter 110 for significant amplification of a gain value of a low-frequency band. For example, the gain value of the low-frequency band may be amplified by increasing a Q factor related to the low-frequency band. In FIG. 4B, a frequency band from about 100 Hz to about 300 Hz is set as the low-frequency band. Although a gain value is increased by significantly increasing a Q factor in the frequency band from about 100 Hz to about 300 Hz in comparison with original frequency response characteristics, the frequency response characteristics are not changed in other frequency bands. Accordingly, speakers having low reproducing capacity in the low-frequency band can provide excellent low bass by selectively increasing the gain value in the low-frequency band.

However, in a case where it is determined that a magnitude of an output sound signal exceeds a threshold value such that distortion may occur in the output sound signals, the sound signal reproducing apparatus 100 does not change the Q factor in the low-frequency band, such that frequency response characteristics of the filter 110 are identical to the original frequency response characteristics of the filter 110. According to exemplary embodiments, the sound signal reproducing apparatus 100 may change frequency response characteristics of the filter 110 to prevent distortion from occurring in sound signals by further decreasing a gain value as compared to the original frequency response characteristics by further reducing a Q factor or a gain value. In other words, the sound signal reproducing apparatus 100 may select a Q factor that is inversely proportional to a magnitude of an output sound signal.

Referring to FIG. 4B, in a case 410 where an output sound signal is 5 V, no distortion occurs when the output sound signal is output via speakers, and thus a gain value in the low-frequency band is increased as compared to the original frequency response characteristics 401.

In a case 420 where an output sound signal is 10 V, no distortion occurs when an output sound signal is output via the speakers, and thus a gain value in the low-frequency band is also increased as compared to the original frequency response characteristics 401. According to exemplary embodiments, an increase in the gain value in the case 420 where the output sound signal is 10 V may be smaller than that in the case 410 where the output sound signal is 5 V.

In a case 430 where an output sound signal is 15 V, a distortion may occur when an output sound signal is output via the speakers or the reliability of the speakers may be deteriorated. Thus, the same frequency response characteristics as the original frequency response characteristic are applied. In other words, a gain value in the low-frequency band is not increased. According to exemplary embodiments, a gain value may be reduced in bands in which the gain value may exceed a threshold value such that distortion may occur in the output sound signal.

As described above, the sound signal reproducing apparatus according to an exemplary embodiment may reproduce sound signals having a quality that is close to real sounds according to a gain value of an output signal by amplifying a low-frequency band in a case where no distortion occurs when the output sound signal is output via speakers or by not amplifying the low-frequency band in a case where it is determined that distortion may occur when the output sound signal is output via the speakers.

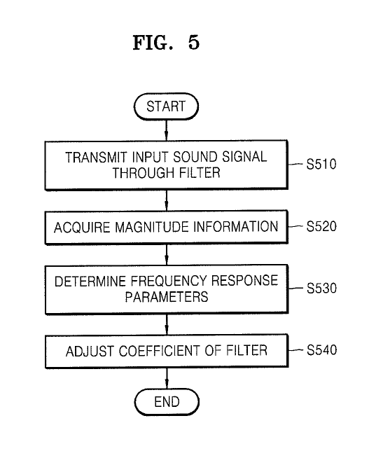

FIG. 5 is a flowchart showing a method of reproducing a sound signal according to an exemplary embodiment.

In operation S510, an output sound signal to be output via speakers is generated by transmitting an input sound signal via a filter. The filter is embodied by using at least one of an IIR filter and a FIR filter and may include a pre-processing filter for simultaneously adjusting frequency characteristics of sound signals according to initial frequency response parameters that are determined when the sound signal reproducing apparatus is manufactured, and a post-processing filter for adaptively adjusting frequency characteristics of sound signals according to magnitudes of output sound signals previously output by the speakers.

Initially, coefficients of the filter are determined according to frequency response characteristics that are determined when a sound signal reproducing apparatus is manufactured. However, once sound signals are output, coefficients of the filter are adaptively adjusted according to magnitudes of the latest output sound signals.

In operation S520, magnitude information is acquired from the output sound signal which has passed through the filter.

In operation S530, frequency response parameters related to frequency responses of the filter are determined based on magnitude information. The frequency response parameters may include at least one of a Q factor, a center frequency, a cut-off frequency, a bandwidth, a gain value, etc. The magnitude of the output sound signal and a mapping table indicating mapping between the magnitudes and the frequency response parameters may be used to determine the frequency response parameters.

For example, if the magnitude of the output sound signal is less than or equal to a threshold point, the frequency response parameters may be determined such that a low-frequency component of a sound signal to be input to the filter is amplified. If the magnitude of the output sound signal is greater than the threshold point, the frequency response parameters may be determined such that frequency response characteristics of the filter are not changed or a gain value decreases.

In operation 540, coefficients of the filter are adjusted based on the determined frequency response parameters. A Q factor may be changed by changing a poll value of a low-frequency band of a transfer function which numerically expresses frequency response characteristics. Then, coefficients of the filter may be determined.

The present inventive concept may also be embodied in a computer readable recording medium that stores a computer programs and can be implemented in general-use digital computers that execute the programs using one or more central processing units.

Examples of the computer readable recording medium include magnetic storage media (e.g., ROM, floppy disks, hard disks, etc.), optical recording media (e.g., CD-ROMs, or DVDs), etc.

While the present inventive concept has been particularly shown and described with reference to exemplary embodiments thereof, it will be understood by those skilled in the art that various changes in form and details may be made therein without departing from the spirit and scope of the present inventive concept as defined by the appended claims. The exemplary embodiments should be considered in descriptive sense only and not for purposes of limitation. Therefore, the scope of the present inventive concept is defined not by the detailed description of the invention but by the appended claims, and all differences within the scope will be construed as being included in the present inventive concept.

What is claimed is:

1. A method of reproducing a sound signal, the method comprising:
generating an output sound signal to be transmitted to speakers by transmitting a first input sound signal through a filter;
acquiring magnitude information of the output sound signal;
determining frequency response parameters related to frequency responses of the filter based on the magnitude information; and
adaptively adjusting coefficients of the filter based on the determined frequency response parameters.

2. The method of claim 1, wherein the determining of the frequency response parameters comprises determining frequency response parameters by using a mapping table which includes information regarding mapping between magnitudes of the output sound signal and frequency response parameters.

3. The method of claim 1, wherein the determining of the frequency response parameters comprises determining the frequency response parameters based on a magnitude of the output sound signal, such that a gain value of a low-frequency component of a second input sound signal, which is input to the filter after the first input sound signal, increases.

4. The method of claim 3, wherein the determining of the frequency response parameters comprises determining the frequency response parameters, such that, if the magnitude of the output sound signal exceeds a threshold point, the gain value of the low-frequency component of the second input sound signal does not increase.

5. The method of claim 3, wherein the determining of the frequency response parameters comprises determining the frequency response parameters, such that the gain value of the low-frequency component of the second input sound signal increases in inverse proportion to the magnitude of the output sound signal.

6. The method of claim 1, wherein the frequency response parameters comprise at least one of a center frequency, a bandwidth corresponding to the center frequency, and a gain value at the center frequency.

7. The method of claim 1, wherein the filter configured to simultaneously adjust frequency characteristics of sound signals according to initial frequency response parameters, and adaptively adjust frequency characteristics of sound signals according to a magnitude of a second output sound signal output by the speakers before the first output sound signal.

8. The method of claim 1, wherein the filter is embodied by using at least one of a finite impulse response (FIR) filter and an infinite impulse response (IIR) filter.

9. A sound signal reproducing apparatus comprising:
a filter that generates an output sound signal to be transmitted to speakers from a first input sound signal;
a magnitude acquiring unit that acquires magnitude information of the output sound signal;
a parameter determining unit that determines frequency response parameters related to frequency responses of the filter based on the magnitude information; and
a coefficient adjusting unit that adaptively adjusts coefficients of the filter based on the determined frequency response parameters.

10. The sound signal reproducing apparatus of claim 9, further comprising a database in which a mapping table which includes information regarding mapping between magnitudes of the output sound signal and frequency response parameters is stored,
wherein the parameter determining unit determines the frequency response parameters based on the magnitude of the output sound signal and the mapping table.

11. The sound signal reproducing apparatus of claim 9, wherein the parameter determining unit determines the frequency response parameters based on a magnitude of the output sound signal, such that a gain value of a low-frequency component of a second input sound signal, which is input to the filter after the first input sound signal, increases.

12. The sound signal reproducing apparatus of claim 11, wherein, if the magnitude of the output sound signal exceeds a threshold point, the parameter determining unit determines the frequency response parameters, such that the gain value of a low-frequency component of the second input sound signal does not increase.

13. The sound signal reproducing apparatus of claim 11, wherein the parameter determining unit determines the frequency response parameters, such that the gain value of a low-frequency component of the second input sound signal increases in inverse proportion to a magnitude of the output sound signal.

14. The sound signal reproducing apparatus of claim 9, wherein the frequency response parameters comprise at least one of a center frequency, a bandwidth corresponding to the center frequency, and a gain value at the center frequency.

15. The sound signal reproducing apparatus of claim 9, wherein the filter configured to simultaneously adjust frequency characteristics of sound signals according to initial frequency response parameters, and adaptively adjust frequency characteristics of sound signals according to a magnitude of a second output sound signal output by the speakers before the first output sound signal.

16. The sound signal reproducing apparatus of claim 9, wherein the filter comprises at least one of a FIR filter and an IIR filter.

17. A computer readable recording medium having recorded thereon a computer program for implementing a method comprising:
generating an output sound signal to be transmitted to speakers by transmitting a first input sound signal through a filter;
acquiring magnitude information of the output sound signal;
determining frequency response parameters related to frequency responses of the filter based on the magnitude information; and
adaptively adjusting coefficients of the filter based on the determined frequency response parameters.

18. A sound signal reproducing apparatus comprising:
a filter that generates an output sound signal to be transmitted to speakers from a first input sound signal, the output sound signal being generated according to one or more filter coefficients;
a magnitude acquiring unit that acquires magnitude information of the output sound signal prior to the output sound signal being transmitted to the speakers;
a parameter determining unit that determines frequency response parameters of the filter based on the magnitude information; and
a coefficient adjusting unit that adaptively adjusts the filter coefficients of the filter based on the determined frequency response parameters.

19. The sound signal reproducing apparatus of claim 18, wherein the frequency response parameters comprise a gain of the filter, and
the parameter determining unit compares the magnitude information with a threshold magnitude, and changes the gain of the filter if the magnitude information is less than or equal to the threshold magnitude.

20. The sound signal reproducing apparatus of claim 18, wherein the magnitude acquiring unit acquires the magnitude information within a frequency band, and the parameter determining unit changes the gain of the filter only for frequencies within the frequency band.
